(19) United States
(12) Patent Application Publication
(10) Pub. No.: US 2019/0043833 A1
(43) Pub. Date: Feb. 7, 2019

(54) SEMICONDUCTOR PACKAGES INCLUDING A PLURALITY OF STACKED DIES

(71) Applicant: SK hynix Inc., Icheon-si Gyeonggi-do (KR)

(72) Inventors: Hyoung Chul KWON, Seoul (KR); Bae Yong KIM, Gwangju (KR); Jong Hyock PARK, Gwangju (KR)

(73) Assignee: SK hynix Inc., Icheon-si Gyeonggi-do (KR)

(21) Appl. No.: 15/919,579

(22) Filed: Mar. 13, 2018

(30) Foreign Application Priority Data
Aug. 3, 2017 (KR) 10-2017-0098672

(51) Int. Cl. H01L 25/065; H01L 23/00; H01L 23/31

(52) U.S. Cl. CPC H01L 25/0657; H01L 23/562; H01L 23/3178; H01L 2225/06582; H01L 2225/06513; H01L 2225/06541; H01L 2225/06555; H01L 23/3185

(57) ABSTRACT

A semiconductor package includes core dies and an encapsulant layer. The core dies are stacked on a base die to leave edge regions of the base die exposed. The encapsulant layer is disposed to cover side surfaces of the core dies and a surface of the exposed edge regions of the base die. The surface of the edge regions of the base die includes a concave/convex-shaped structure which is at least partially filled by the encapsulant layer.

### CROSS-REFERENCE TO RELATED APPLICATIONS

The present application claims priority under 35 U.S.C 119(a) to Korean Application No. 10-2017-0098672, filed on Aug. 3, 2017, which is incorporated herein by reference in its entirety.

### BACKGROUND

### 1. Technical Field

The present disclosure generally relates to semiconductor package technologies and, more particularly, to semiconductor packages including a plurality of stacked dies.

### 2. Related Art

In the electronics industry, techniques for vertically stacking a plurality of semiconductor dies in a three-dimensional semiconductor package is increasingly in demand with the development of multi-functional electronic systems, and a larger storage capacity of and smaller electronic systems or products. In addition, a high bandwidth memory (HBM) solution technique has been required to obtain a fast signal transmission speed. Even though a plurality of semiconductor dies is stacked in a semiconductor package, a lot of effort has been focused on reducing the size of the semiconductor package. Accordingly, a distance between an outer side surface of an encapsulant of the semiconductor package and a side surface of a stack of the semiconductor dies has been reduced which causes a delamination phenomenon where the encapsulant of the semiconductor package detaches from the semiconductor dies.

### SUMMARY

According to an embodiment, a semiconductor package includes core dies and an encapsulant layer. The core dies are stacked on a base die to leave edge regions of the base die exposed. The encapsulant layer is disposed to cover side surfaces of the core dies and a surface of the exposed edge regions of the base die. The surface of the edge regions of the base die includes a concave/convex-shaped structure which is at least partially filled by the encapsulant layer.

According to another embodiment, a semiconductor package includes a first semiconductor package, an interconnection structured layer, and a semiconductor device. The first semiconductor package includes core dies stacked on a base die to leave edge regions of the base die exposed and a first encapsulant layer disposed to cover side surfaces of the core dies as well as a surface of the exposed edge regions of the base die. The surface of the edge regions of the base die includes a concave/convex-shaped structure which is at least partially filled by the encapsulant layer. The first semiconductor package is mounted on the interconnection structured layer. The semiconductor device is disposed on the interconnection structured layer to be located beside the first semiconductor package. A second encapsulant layer is disposed to cover the first semiconductor package and the semiconductor device.

### BRIEF DESCRIPTION OF THE DRAWINGS

Various embodiments of the present disclosure will become more apparent in view of the attached drawings and accompanying detailed description, in which:

FIGS. 1 and 2 are cross-sectional views illustrating a semiconductor package according to an embodiment;

FIG. 3 is a plan view illustrating a semiconductor package according to an embodiment;

FIG. 4 is a cross-sectional view illustrating a semiconductor package according to another embodiment;

FIG. 5 is a block diagram illustrating an electronic system employing a memory card including at least one of the semiconductor packages according to some embodiments; and

FIG. 6 is a block diagram illustrating another electronic system including at least one of the semiconductor packages according to some embodiments.

### DETAILED DESCRIPTION OF THE EMBODIMENTS

The terms used herein may correspond to words selected in consideration of their functions in the embodiments, and the meanings of the terms may be construed to be different according to the ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element, but not used to define the element itself or to mean a particular sequence.

A semiconductor package may include electronic devices such as semiconductor chips or semiconductor dies. The semiconductor chips or the semiconductor dies may be obtained by separating a semiconductor substrate such as a wafer into a plurality of pieces using a die sawing process. The semiconductor chips may correspond to memory chips, logic chips (including application specific integrated circuits (ASIC) chips), or system-on-chips (SoC). The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The logic chips may include logic circuits which are integrated on the semiconductor substrate. The semiconductor package may be employed in communication systems such as mobile phones, electronic systems associated with biotechnology or health care, or wearable electronic systems.

The same reference numerals refer to the same elements throughout the specification. Thus, even though a reference numeral is not mentioned or described with reference to a drawing, the reference numeral may be mentioned or described with reference to another drawing. In addition, even though a reference numeral is not shown in a drawing, the reference numeral may be mentioned or described with reference to another drawing.

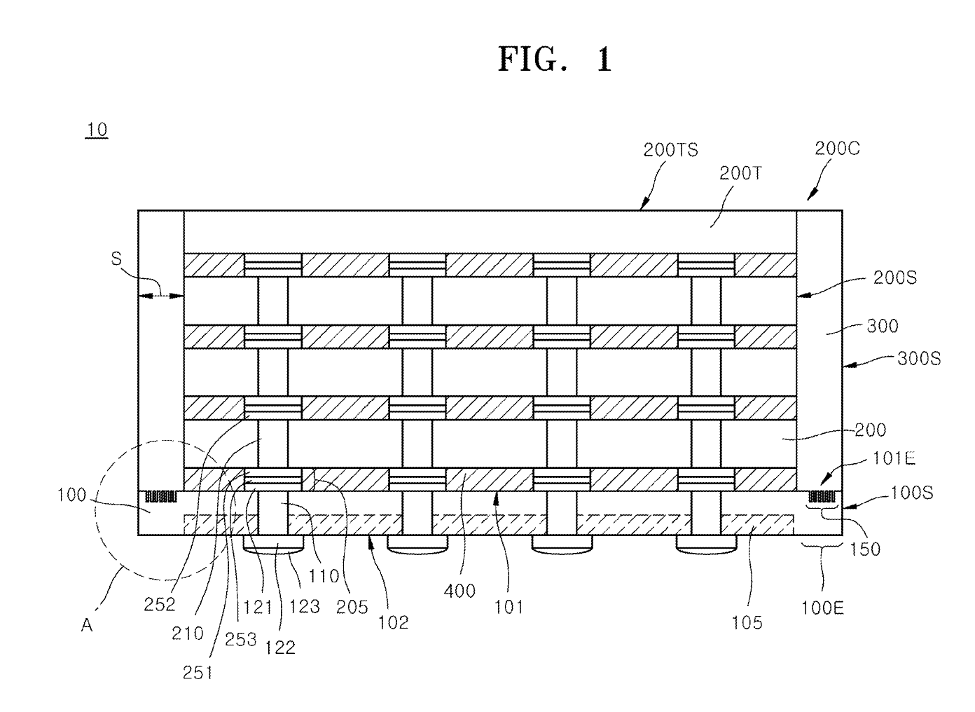

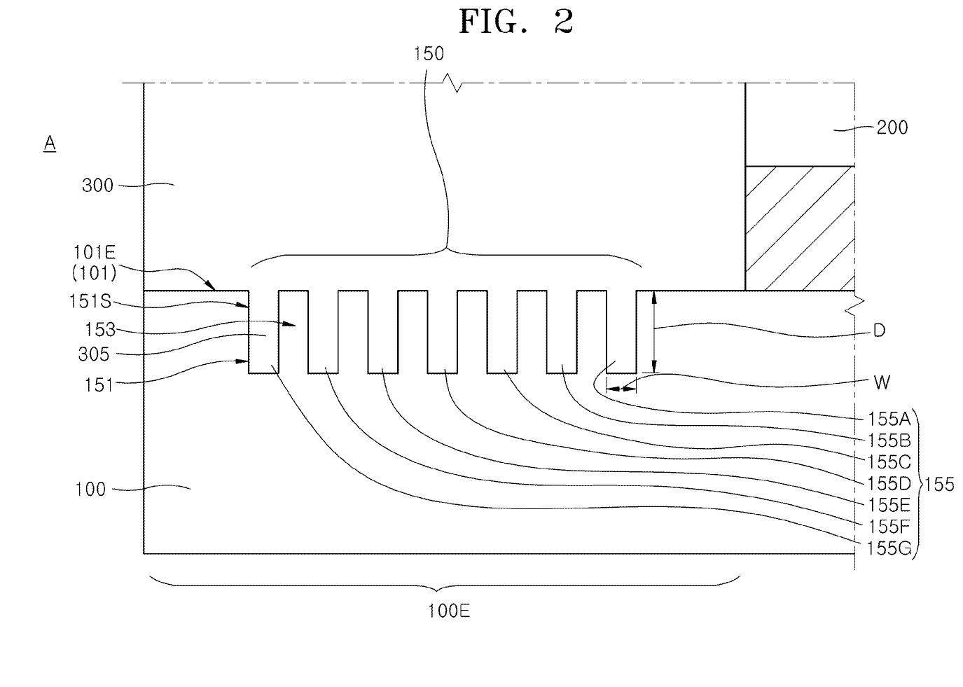

FIG. 1 is a cross-sectional view illustrating a structure of a semiconductor package 10 according to an embodiment. FIG. 2 is an enlarged view illustrating portion ‘A’ of FIG. 1. FIG. 3 is a plan view illustrating the semiconductor package 10 of FIG. 1.

Referring to FIG. 1, the semiconductor package 10 may include a base die 100 and core dies 200 stacked on the base die 100. The base die 100 may have a width greater than widths of the core dies 200. The core dies 200 may have substantially a same size, for example, the core dies 200 may have a same width. Edge regions 100E of the base die 100 may laterally protrude from side surfaces of the core dies 200. The core dies 200 may be vertically stacked on a first surface 101 (corresponding to a backside surface) of the base die 100 to leave edge surfaces 101E of the edge regions 100E of the base die 100 exposed. The edge surfaces 101E of the base die 100 may be portions of the first surface 101 of the base die 100.

The semiconductor package 10 may also include an encapsulant layer 300. The encapsulant layer 300 may be disposed to cover the edge surfaces 101E of the base die 100 and side surfaces 200S of a stack 200C of the core dies 200. The encapsulant layer 300 may be disposed to leave a top surface 200TS of a topmost core die 200T of the core die stack 200C exposed. Because the encapsulant layer 300 leaves the top surface 200TS of the topmost core die 200T exposed, heat generated by operation of the core dies 200 may be efficiently emitted so that the performance of the semiconductor package 10 is not degraded. The encapsulant layer 300 may cover a surface of the exposed edge regions 100E of the base die 100. In some embodiments, the encapsulant layer 300 may extend over the top surface 200TS to cover the top surface 200TS and the side surfaces 200S of the core die stack 200C.

As the size of the semiconductor package 10 is reduced, a width S of the encapsulant layer 300 may also be reduced. The width S of the encapsulant layer 300 may correspond to a distance between the side surface 200S of the core die stack 200C and an outer side surface 300S of the encapsulant layer 300. The outer side surface 300S of the encapsulant layer 300 may be vertically aligned with a side surface 100S of the base die 100. The outer side surface 300S of the encapsulant layer 300 and the side surface 100S of the base die 100 may constitute a side surface of the semiconductor package 10. Thus, the width S of the encapsulant layer 300 may correspond to a width of the edge region 100E of the base die 100. The width of the edge region 100E of the base die 100 may be less than a total width of the base die 100. As a result, the width S of the encapsulant layer 300 may be narrow as compared to the total width of the base die 100.

In general, the edge surfaces 101E of the base die 100 have a flat profile. In such a case, a planar area of an interface surface between the encapsulant layer 300 and the edge surfaces 101E of the base die 100 may be minimized to reduce an adhesive strength between the encapsulant layer 300 and the base die 100. If the adhesive strength between the encapsulant layer 300 and the base die 100 is reduced, the encapsulant layer 300 is not securely fastened to the base die 100. Therefore, the base die 100 may become detached from the encapsulant layer 300 at inopportune times.

According to an embodiment, the edge surfaces 101E of the base die 100 may have a concave/convex-shaped structure 150. The concave/convex-shaped structure 150 may increase a surface area of the edge surfaces 101E. Thus, an interface area between the encapsulant layer 300 and the edge surfaces 101E of the base die 100 may increase to enhance an adhesive strength between the encapsulant layer 300 and the base die 100.

As illustrated in FIG. 2, the concave/convex-shaped structure 150 may include concave portions 151 and convex portions 153. Each of the concave portions 151 may correspond to a groove recessed in the edge surface 101E. Accordingly, each of the concave portions 151 may be recessed in a surface of the edge regions 100E of the base die 100, and the concave/convex-shaped structure 150 may be at least partially filled by the encapsulant layer 300. Each of the convex portions 153 may correspond to a protrusion between two adjacent concave portions 151. That is, the convex portions 153 may be defined by the concave portions 151. The convex portions 153 located between the concave portions 151 may protrude from bottom surfaces of the concave portions 151.

Side surfaces 151S of the concave portions 151 may extend from the edge surface 101E toward an inside region of the base die 100. Further, portions of the encapsulant layer 300 may protrude into the concave portions 151 to, for example, fill the concave portions 151. Thus, an interface area (i.e., a contact area) between the encapsulant layer 300 and the edge surfaces 101E of the base die 100 may increase by a total area of the side surfaces 151S of the concave portions 151, as compared to a case that the edge surfaces 101E have a flat profile. Accordingly, an adhesive strength between the encapsulant layer 300 and the edge surfaces 101E of the base die 100 may increase to prevent or suppress the encapsulant layer 300 from being lifted and/or separated from the base die 100.

The encapsulant layer 300 may extend into the empty spaces of the concave portions 151 to provide protrusions 305 of the encapsulant layer 300. The protrusions 305 of the encapsulant layer 300 may act as spikes or anchors that fix the encapsulant layer 300 to the base die 100. Thus, an adhesive strength between the encapsulant layer 300 and the base die 100 may be enhanced.

A width W of each of the concave portions 151 may be determined according to a width of the edge regions 100E of the base die 100. The width W of each concave portion 151 may be determined according to the number of the concave portions 151. The width W of each concave portion 151 may be set to be in the range of approximately a few micrometers to several tens of micrometers. A depth D of each of the concave portions 151 may be determined according to a thickness of the base die 100. The thicker the based die 100 the deeper each concave portion 151 may be. The depth D of each concave portion 151 may be set to be within the range of approximately a few micrometers to several tens of micrometers.

As illustrated in FIGS. 2 and 3, each of the concave portions 151 may be formed to have a trench shape. The concave portions 151 having a trench shape may be disposed in the edge regions 100E of the base die 100. The concave portions 151 may be trenches 155 that extend in a direction parallel to each of the side surfaces 200S of the core die stack 200C in a plan view of FIG. 3. Each of the trenches 155 may have a straight line shape extending to be parallel with the side surfaces 200S of the core die stack 200C in a plan view of FIG. 3. The trenches 155A, 155B, 155C, 155D, 155E, 155F, 155G may be parallel with each other. The concave portions 151 having a trench shape may extend in a direction parallel with each of the side surfaces 100S of the base die 100 (or each of the outer side surfaces 300S of the encapsulant layer 300) in a plan view of FIG. 3. The concave portions 151 having a trench shape may extend along the four side surfaces 200S of the core die stack 200C in a plan view of FIG. 3. The concave portions 151 having a trench shape may extend to surround the core die stack 200C in a plan view of FIG. 3.

The concave portions 151 having a trench shape may be formed by removing portions of the edge regions 100E of the base die 100. For example, the concave portions 151 having a trench shape may be formed by removing portions of the edge regions 100E of the base die 100 using a sawing process or a laser process. The core die stack 200C may be disposed adjacent to the edge regions 100E of the base die 100. Thus, if the concave portions 151 are formed to extend perpendicular to the side surfaces 200S of the core die stack 200C in a plan view of FIG. 3, the core die stack 200C may be damaged by a blade used in the sawing process for forming the concave portions 151. Accordingly, the present disclosure may in some instances preclude concave portions 151 formed to extend in a direction perpendicular to the side surfaces 200S of the core die stack 200C in a plan view of FIG. 3.

The concave portions 151 having a trench shape may intersect each other in each of corner portions 109 of the base die 100, as illustrated in FIG. 3. Thus, the concave/convex-shaped structure 150 may include a grid-shaped concave portion 151L which may be provided in each of the corner portions 109 of the base die 100 in a plan view. As a result, island-shaped convex portions 153L may be provided to be isolated from each other in each of the corner portions 109 of the base die 100. That is, each of the island-shaped convex portions 153L may be defined and surrounded by the grid-shaped concave portion 151L. If the grid-shaped concave portions 151L are disposed to provide the island-shaped convex portions 153L, an interface area between the encapsulant layer 300 and the base die 100 may increase to significantly enhance an adhesive strength between the encapsulant layer 300 and the base die 100 as compared with a case without the island-shaped convex portions 153L and grid-shaped concave portions 151L. In particular, if the concave portions 151 are formed to provide the grid-shaped concave portions 151L in the corner portions 109 of the base die 100, the grid-shaped concave portions 151L in the corner portions 109 may be very effective in suppressing a phenomenon that the encapsulant layer 300 is detached from the base die 100 because a stress causing a delamination phenomenon of the encapsulant layer 300 is concentrated in the corner portions 109 rather than in non-corner regions of the base die 100.

Referring again to FIG. 1, the base die 100 may include a plurality of through silicon vias (TSVs). The base die 100 may include a semiconductor body layer, and circuit elements may be integrated in or on the semiconductor body layer. In such a case, first through vias 110 may be disposed to vertically penetrate the semiconductor body layer (e.g., a silicon layer) of the base die 100. First connection terminals 122 for electrically connecting the base die 100 to an external device may be disposed on a second surface 102 of the base die 100 opposite to the core die stack 200C. Second connection terminals 121 may be disposed on the first surface 101 of the base die 100. The second connection terminals 121 may electrically connect the base die 100 to the core die stack 200C.

A surface on which the first connection terminals 122 are disposed may be different from a surface on which the second connection terminals 121 are disposed. The first connection terminals 122 may be disposed to overlap with the first through vias 110, respectively. The second connection terminals 121 may also be disposed to overlap with the first through vias 110, respectively. The first connection terminals 122 may be disposed to respectively overlap with the second connection terminals 121 in a plan view. The first connection terminals 122 may be electrically connected to the first through vias 110, respectively. The second connection terminals 121 may also be electrically connected to the first through vias 110, respectively. Thus, there may be provided signal paths including the first connection terminals 122, the first through vias 110, and second connection terminals 121. The signal paths may be disposed to pass through the base die 100.

The first connection terminals 122 may be bumps protruding from the second surface 102 of the base die 100. Each of the bumps corresponding to the first connection terminals 122 may include copper. A first conductive adhesive layer 123 may be disposed on ends of the first connection terminals 122 opposite to the base die 100. The first conductive adhesive layer 123 may include a solder layer. The solder layer used as the first conductive adhesive layer 123 may include an alloy material of tin (Sn) and silver (Ag). A barrier layer such as a nickel layer may be additionally disposed between the first conductive adhesive layer 123 and the first connection terminals 122. The second connection terminals 121 may be copper bumps protruding from the first surface 101 of the base die 100.

The base die 100 may include an active layer 105 adjacent to the second surface 102 to have circuit elements constituting an integrated circuit. Each of the core dies 200 may have a function different from a function of the integrated circuit formed in the base die 100. For example, the core dies 200 may be memory devices, and the integrated circuit of the base die 100 may include a controller for controlling operations of the core dies 200. If the core dies 200 are memory devices having a substantially same feature and function, the semiconductor package 10 may have a large capacity of memory.

The semiconductor package 10 may be configured to have a high bandwidth memory (HBM) structure. The base die 100 and the core dies 200 may constitute a HBM structure. In such a case, each of the core dies 200 may be a DRAM device including banks storing data, and the base die 100 may include a circuit for testing the core dies 200 and a circuit for soft-repairing the core dies 200. That is, the base die 100 may output an address and a command for performing a write operation and a read operation of the core dies 200, for example, DRAM devices. The base die 100 may include an interface having a physical layer (PHY) for signal transmission between the base die 100 and the core dies 200 or between the base die 100 and an external device. The base die 100 may be electrically connected to the core dies 200 through the TSVs which are disposed to penetrate the core dies 200 and the base die 100.

Second through vias 210 may be disposed to vertically penetrate each of the core dies 200. A third connection terminal 252 and a fourth connection terminal 251 may be disposed on both ends of each of the second through vias 210, respectively. If the third connection terminal 252 is disposed on one surface of a certain die of the core dies 200, the fourth connection terminal 251 may be disposed on another surface of the certain die of the core dies 200. Thus, signal paths including the third connection terminals 152, the second through vias 210, and the second connection terminals 151 may be provided in the core die stack 200C. The signal paths may be disposed to pass through the core dies 200. Each of the third and fourth connection terminals 152 and 151 may be a bump including copper.

The base die 100 and a bottommost the core die 200 of the core die stack 200C may be connected to the each other through bump connection structures 205. Each of the bump connection structures 205 may be configured to include one of the second connection terminals 121 and one of the fourth connection terminals 251. In such a case, a second conductive adhesive layer 253 may be additionally disposed between the second connection terminals 121 and the fourth connection terminals 251. The core dies 200 may also be electrically connected to each other through the bump connection structures 205.

A non-conductive adhesive layer 400 may be disposed between the base die 100 and the core dies 200. The non-conductive adhesive layer 400 may include a non-conductive film (NCF).

At least one of the semiconductor packages 10 may be employed in another semiconductor package. For example, the semiconductor package 10 may be included in a system-in-package (SIP).

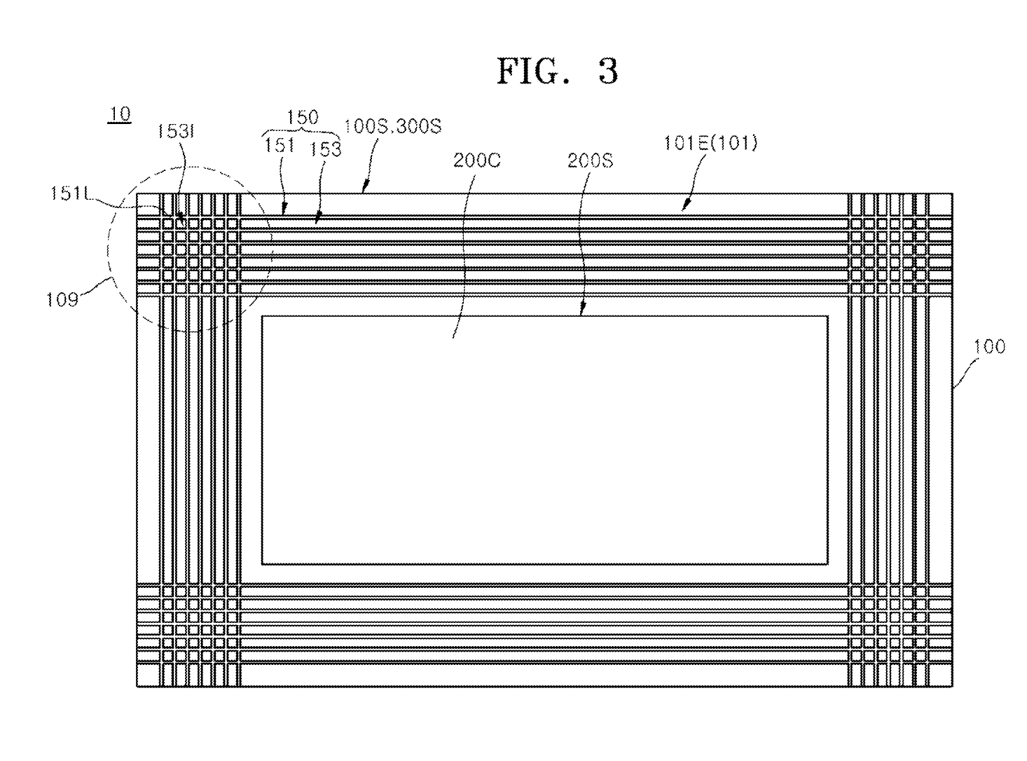

FIG. 4 is a cross-sectional view illustrating a semiconductor package 20 corresponding to a system-in-package according to another embodiment.

Referring to FIG. 4, the semiconductor package 20 may include at least one of the semiconductor packages 10 corresponding to a first semiconductor package of the semiconductor package 20. The first semiconductor package 10 may act as a package-in-package embedded in a single SIP. The first semiconductor package 10 may be mounted on an interconnection structured layer 2200. The interconnection structured layer 2200 may correspond to an interposer. A semiconductor device 2300 may be disposed on the interconnection structured layer 2200. The semiconductor device 2300 may be a semiconductor die or a semiconductor package.

The first semiconductor package 10 and the semiconductor device 2300 may be disposed side-by-side on a surface of the interconnection structured layer 2200. Another first semiconductor package 10 may be disposed on the interconnection structured layer 2200. In such a case, the semiconductor device 2300 may be disposed between the couple of first semiconductor packages 10. Each of the first semiconductor packages 10 may act as an HBM device. The semiconductor device 2300 may include a system-on-chip (SoC). The semiconductor device 2300 may be a processor chip that communicates with the first semiconductor packages 10 in a fast signal transmission speed through a high bandwidth interface. The processor chip acting as the semiconductor device 2300 may be an application specific integrated circuit (ASIC) chip including a central processing unit (CPU) or a graphic processing unit (GPU), a microprocessor or a microcontroller, an application processor (AP), a digital signal processing core, and an interface for signal transmission.

The semiconductor device 2300 may be connected to the interconnection structured layer 2200 through fifth connection terminals 2307. Each of the fifth connection terminals 2307 may include a bump. The first semiconductor packages 10 may be connected to the interconnection structured layer 2200 through the first connection terminals (122 of FIG. 1). A second encapsulant layer 2400 may be disposed on the interconnection structured layer 2200 to cover a first encapsulant layer corresponding to the encapsulant layer (300 of FIG. 1) of the first semiconductor packages 10. The second encapsulant layer 2400 may also extend to cover the semiconductor device 2300.

The interconnection structured layer 2200 may be connected to a package substrate 2500 through sixth connection terminals 2207. Each of the sixth connection terminals 2207 may include a bump having a diameter greater than a diameter of the fifth connection terminals 2307. Seventh connection terminals 2507 may be disposed on a surface of the package substrate 2500 opposite to the interconnection structured layer 2200. The seventh connection terminals 2507 may electrically connect the package substrate 2500 to an external device. The seventh connection terminals 2507 may be solder balls.

The interconnection structured layer 2200 may include first signal paths 2201 through which signals between the first semiconductor package 10 and the semiconductor device 2300 are directly transmitted. The first signal paths 2201 may be horizontal signal paths which are disposed horizontally in the interconnection structured layer 2200. The interconnection structured layer 2200 may include second signal paths 2203 that electrically connect the semiconductor device 2300 to the package substrate 2500. The second signal paths 2203 may be vertical signal paths which are disposed to vertically penetrate the interconnection structured layer 2200. The interconnection structured layer 2200 may include third signal paths 2205 that electrically connect the first semiconductor packages 10 to the package substrate 2500. The third signal paths 2205 may be vertical signal paths which are disposed to vertically penetrate the interconnection structured layer 2200.

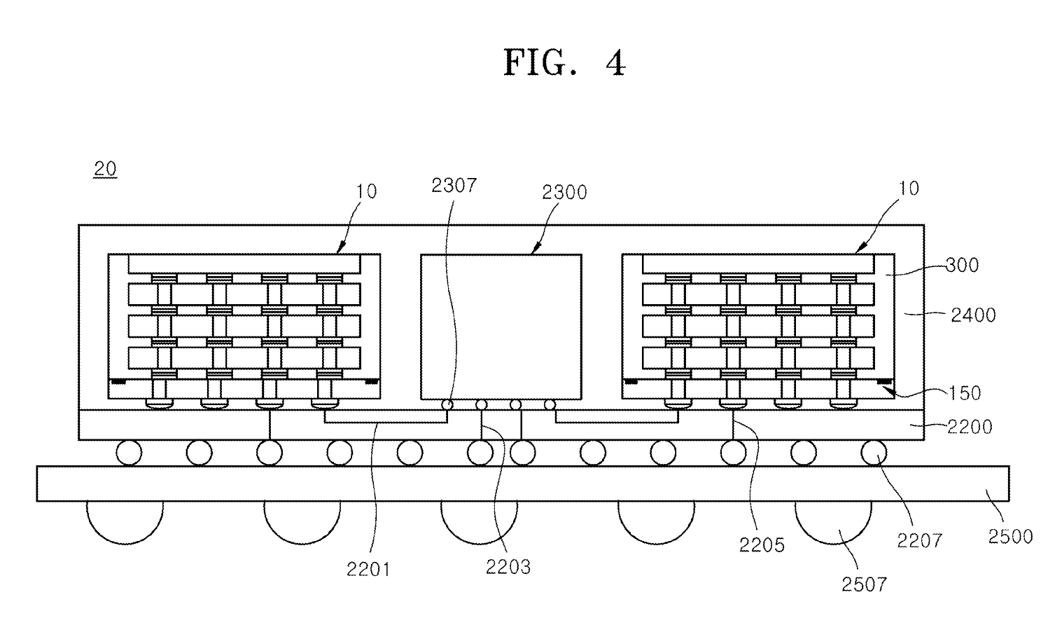

FIG. 5 is a block diagram illustrating an electronic system including a memory card 7800 employing at least one of the semiconductor packages according to the embodiments. The memory card 7800 includes a memory 7810 such as a nonvolatile memory device, and a memory controller 7820. The memory 7810 and the memory controller 7820 may store data or read out the stored data. The memory card 7800 may be configured to include at least one of the semiconductor packages (10 and 20 of FIGS. 1 and 4) according to the embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

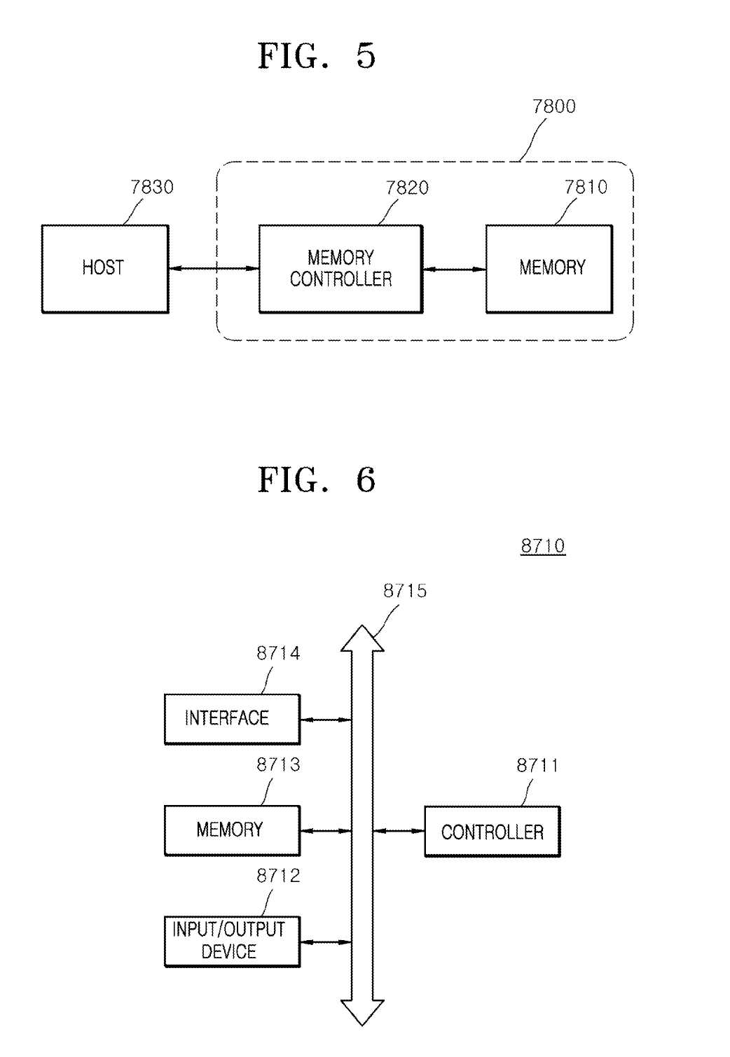

FIG. 6 is a block diagram illustrating an electronic system 8710 including at least one of the packages according to the embodiments. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more of a microprocessor, digital signal processor, microcontroller, and/or logic device capable of performing the same functions as these components. The controller 8711 and the memory 8713 may be configured to include at least one of the semiconductor packages (10 and 20 of FIGS. 1 and 4) according to the embodiments of the present disclosure. The input/output device 8712 may include at least one selected among a keypad, a keyboard, a display device, a touchscreen, and so forth. The memory 8713 may be a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may also include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 may be equipment capable of performing wireless communications, the electronic system 8710 may be used in a communication system using a technique of CDMA (code division multiple access), GSM (global system for mobile communications), NADC (north American digital cellular), E-TDMA (enhanced-time division multiple access), WCDAM (wideband code division multiple access), CDMA2000, LTE (long term evolution), or Wibro (wireless broadband Internet).

Embodiments of the present disclosure have been disclosed for illustrative purposes. Those skilled in the art will appreciate that various modifications, additions, and substitutions are possible, without departing from the scope and spirit of the present disclosure and the accompanying claims.

What is claimed is:

1. A semiconductor package comprising:
core dies stacked on a base die to leave edge regions of the base die exposed; and
an encapsulant layer disposed to cover side surfaces of the core dies as well as a surface of the exposed edge regions of the base die,
wherein the surface of the edge regions of the base die includes a concave/convex-shaped structure which is at least partially filled by the encapsulant layer.

2. The semiconductor package of claim 1, wherein the concave/convex-shaped structure includes concave portions recessed from the surface of the edge regions of the base die and convex portions located between the concave portions to protrude from bottom surfaces of the concave portions.

3. The semiconductor package of claim 2, wherein the concave portions are trenches that extend in a direction parallel to the side surfaces of the core dies in a plan view.

4. The semiconductor package of claim 3, wherein each of the trenches has a straight line shape extending to be parallel to the side surfaces of the core dies in a plan view.

5. The semiconductor package of claim 3, wherein the trenches are parallel with each other.

6. The semiconductor package of claim 2, wherein the encapsulant layer extends into empty spaces of the concave portions to provide protrusions of the encapsulant layer.

7. The semiconductor package of claim 1, wherein the concave/convex-shaped structure includes grid-shaped concave portions which are respectively located at corner portions of the base die, in a plan view.

8. The semiconductor package of claim 1, wherein side surfaces of the base die are vertically aligned with outer side surfaces of the encapsulant layer, respectively.

9. The semiconductor package of claim 1, wherein the base die and the core dies constitute a high bandwidth memory (HBM) device.

10. The semiconductor package of claim 1, wherein the base die and the core dies are electrically connected to each other by through silicon vias (TSVs).

11. A semiconductor package comprising:
a first semiconductor package including core dies stacked on a base die to leave edge regions of the base die exposed and a first encapsulant layer disposed to cover side surfaces of the core dies as well as a surface of the exposed edge regions of the base die, wherein the surface of the edge regions of the base die includes a concave/convex-shaped structure which is at least partially filled by the encapsulant layer;
an interconnection structured layer on which the first semiconductor package is mounted;
a semiconductor device disposed on the interconnection structured layer to be located beside the first semiconductor package; and
a second encapsulant layer covering the first semiconductor package and the semiconductor device.

12. The semiconductor package of claim 11, wherein the concave/convex-shaped structure includes concave portions recessed from the surface of the edge regions of the base die and convex portions located between the concave portions to protrude from bottom surfaces of the concave portions.

13. The semiconductor package of claim 12, wherein the concave portions are trenches that extend in a direction parallel to the side surfaces of the core dies in a plan view.

14. The semiconductor package of claim 12, wherein the first encapsulant layer extends into empty spaces of the concave portions to provide protrusions of the encapsulant layer.

15. The semiconductor package of claim 11, wherein the concave/convex-shaped structure includes grid-shaped concave portions which are respectively located at corner portions of the base die, in a plan view.

16. The semiconductor package of claim 11, wherein the base die and the core dies constitute a high bandwidth memory (HBM) device.

17. The semiconductor package of claim 11, wherein the base die and the core dies are electrically connected to each other by through silicon vias (TSVs).

18. The semiconductor package of claim 11, wherein the semiconductor device includes a system-on-chip (SoC).

19. The semiconductor package of claim 11, wherein the interconnection structured layer includes an interposer.

20. The semiconductor package of claim 11, wherein the interconnection structured layer includes horizontal signal paths that directly connect the first semiconductor package to the semiconductor device.
